(19) United States
(12) Patent Application Publication
(10) Pub. No.: US 2024/0319557 A1
(43) Pub. Date: Sep. 26, 2024

(54) ELECTROPHORETIC DISPLAY DEVICE

(71) Applicant: E Ink Holdings Inc., Hsinchu (TW)

(72) Inventors: Deng-Kuen Shiau, Hsinchu (TW); Yue-Feng Lin, Hsinchu (TW); Chih-Chia Chen, Hsinchu (TW)

(73) Assignee: E Ink Holdings Inc., Hsinchu (TW)

(21) Appl. No.: 18/603,220

(22) Filed: Mar. 13, 2024

Related U.S. Application Data
(60) Provisional application No. 63/453,168, filed on Mar. 20, 2023.

(51) Int. Cl. G02F 1/167; G02F 1/1343; G02F 1/16756; G02F 1/1676

(52) U.S. Cl. CPC G02F 1/167; G02F 1/13439; G02F 1/16756; G02F 1/1676

(57) ABSTRACT

An electrophoretic display device including a first stretchable material layer, a first stretchable electrode layer, a stretchable electrophoretic display medium layer, multiple second stretchable electrode layers, an insulation layer, and a third stretchable electrode layer. The first stretchable electrode layer is disposed on the first stretchable material layer. The stretchable electrophoretic display medium layer is disposed on the first stretchable electrode layer. The second stretchable electrode layers are separately disposed on the stretchable electrophoretic display medium layer, so that the stretchable electrophoretic display medium layer forms multiple display regions. The insulation layer is disposed on the second stretchable electrode layers, and has multiple through holes in which multiple conductive materials are respectively filled. The third stretchable electrode layer is disposed on the insulation layer, and is electrically connected to the second stretchable electrode layers through the conductive materials, respectively.

### CROSS-REFERENCE TO RELATED APPLICATION

This application claims the priority benefit of U.S. provisional application Ser. No. 63/453,168, filed on Mar. 20, 2023. The entirety of the above-mentioned patent application is hereby incorporated by reference herein and made a part of this specification.

### BACKGROUND

### Technical Field

The disclosure relates to a display device, and in particular to an electrophoretic display device.

### Description of Related Art

With the advancement of technology, various display media are widely used in various display applications, such as: televisions, laptops, electronic paper (e-paper) books, mobile phones, large advertising billboards, and various electronic labels and in mold electronics (IME) in stores, etc.

The current segment technology applications in electronic paper are mainly flat surfaces, such as flat outdoor array displays and flat installation art. The base materials are mostly glass or non-stretchable plastic. Although the segmented display device has the advantage of low power consumption, the application level is relatively limited due to the non-curved surface.

### SUMMARY

The disclosure provides an electrophoretic display device that may be disposed on a curved surface and may also be combined with segment technology.

An embodiment of the disclosure provides an electrophoretic display device, including a first stretchable material layer, a first stretchable electrode layer, a stretchable electrophoretic display medium layer, multiple second stretchable electrode layers, an insulation layer, and a third stretchable electrode layer. The first stretchable electrode layer is disposed on the first stretchable material layer. The stretchable electrophoretic display medium layer is disposed on the first stretchable electrode layer. The second stretchable electrode layers are separately disposed on the stretchable electrophoretic display medium layer, so that the stretchable electrophoretic display medium layer forms multiple display regions. The insulation layer is disposed on the second stretchable electrode layers and has multiple through holes in which multiple conductive materials are respectively filled. The third stretchable electrode layer is disposed on the insulation layer, and is electrically connected to the second stretchable electrode layers through the conductive materials, respectively.

An embodiment of the disclosure provides an electrophoretic display device, including the first stretchable material layer, the first stretchable electrode layer, the stretchable electrophoretic display medium layer, the second stretchable electrode layer, the insulation layer, and the third stretchable electrode layer. The first stretchable electrode layer is disposed on the first stretchable material layer. The stretchable electrophoretic display medium layer is disposed on the first stretchable electrode layer. The second stretchable electrode layer is disposed on the stretchable electrophoretic display medium layer, so that the stretchable electrophoretic display medium layer forms the display region. The insulation layer is disposed on the second stretchable electrode layer and has the through hole, and the through hole is filled with the conductive material. The third stretchable electrode layer is disposed on the insulation layer, and is electrically connected to the second stretchable electrode layer through the conductive material.

In the electrophoretic display device according to the embodiment of the disclosure, since a variety of stretchable materials are used to form various layer structures, the electrophoretic display device according to the embodiment of the disclosure may be disposed on the curved surface and curve as the surface curves. In the electrophoretic display device according to another embodiment of the disclosure, in addition to using the variety of stretchable materials to form the various layer structures, the second stretchable electrode layers are used to be separately disposed on the stretchable electrophoretic display medium layer, so that the stretchable electrophoretic display medium layer forms the display regions. Therefore, the electrophoretic display device according to the embodiment of the disclosure may be disposed on the curved surface and curve as the surface curves, and may be combined with segment technology at the same time.

### BRIEF DESCRIPTION OF THE DRAWINGS

FIG. 1 is a partial cross-sectional schematic view of an electrophoretic display device according to an embodiment of the disclosure.

FIG. 2 is a schematic top view of the electrophoretic display device of FIG. 1.

FIG. 3 is a partial cross-sectional schematic view of an electrophoretic display device according to another embodiment of the disclosure.

### DESCRIPTION OF THE EMBODIMENTS

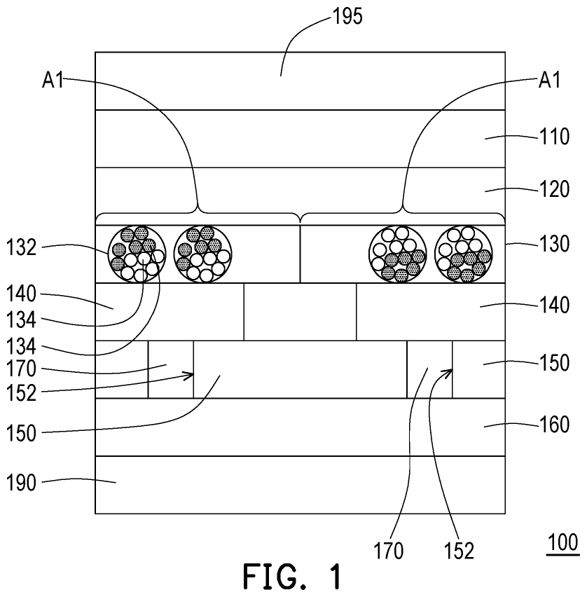

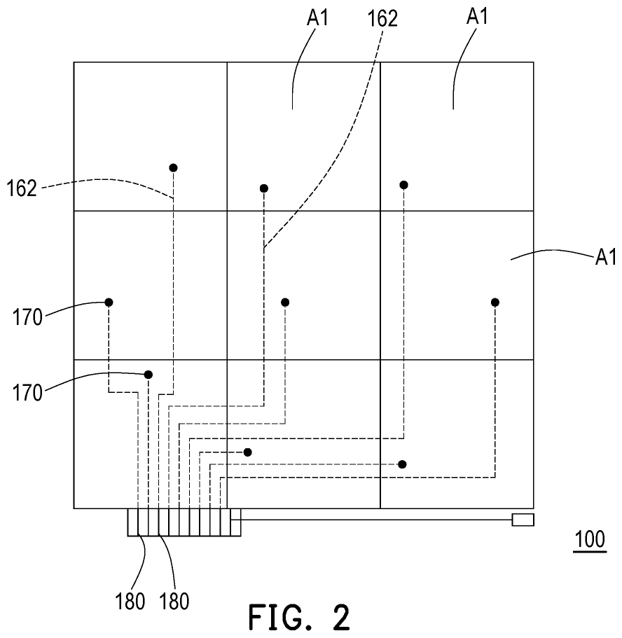

FIG. 1 is a partial cross-sectional schematic view of an electrophoretic display device according to an embodiment of the disclosure. FIG. 2 is a schematic top view of the electrophoretic display device of FIG. 1. Referring to FIGS. 1 and 2, an electrophoretic display device 100 of this embodiment includes a first stretchable material layer 110, a first stretchable electrode layer 120, a stretchable electrophoretic display medium layer 130, multiple second stretchable electrode layers 140, an insulation layer 150, and a third stretchable electrode layer 160. The first stretchable electrode layer 120 is disposed on the first stretchable material layer 110. The stretchable electrophoretic display medium layer 130 is disposed on the first stretchable electrode layer 120. The second stretchable electrode layers 140 are separately disposed on the stretchable electrophoretic display medium layer 130 so that the stretchable electrophoretic display medium layer 130 forms multiple display regions A1. FIG. 1 shows two display regions A1 as a representative. In fact, the electrophoretic display device 100 may also have more display regions A1. FIG. 2 shows an example of nine display regions A1. The display regions A1 may be arranged in an array.

The insulation layer 150 is disposed on the second stretchable electrode layers 140 and has multiple through holes 152. The through holes 152 are respectively filled with multiple conductive materials 170. In this embodiment, the insulation layer 150 may be stretchable and may be formed by a stretchable material. The third stretchable electrode layer 160 is disposed on the insulation layer 150, and is electrically connected to the second stretchable electrode layers 140 through the conductive materials 170, respectively. The second stretchable electrode layers 140 of different display regions A1 may be independently and electrically connected to different pads 180 through different traces 162 in the third stretchable electrode layer 160, respectively. In this way, voltages may be applied to the pads independently to control the display states of these display regions A1 independently and respectively.

In this embodiment, the electrophoretic display device 100 further includes a second stretchable material layer 190 disposed on the third stretchable electrode layer 160.

In the electrophoretic display device 100 of this embodiment, a variety of stretchable materials are used to form various layer structures, and the second stretchable electrode layers 140 are used to be separately disposed on the stretchable electrophoretic display medium layer 130, so that the stretchable electrophoretic display medium layer 130 forms the display regions A1. The stretchable electrophoretic display medium layer 130 may be a whole piece or a combination of multiple pieces. Therefore, the electrophoretic display device 100 of this embodiment may be disposed on the curved surface and curve as the surface curves to achieve a conformal effect, and may also be combined with segment technology. In this embodiment, a lower surface of the second stretchable material layer 190 may be attached to any shaped surface (such as various simple or complex curved surfaces), such as being attached to a home appliance or indicating device with the curved surface to increase a display diversity of home appliances or indicating devices.

In this embodiment, a material of the first stretchable material layer 110 and the second stretchable material layer 190 is, for example, amorphous polyethylene terephthalate (APET). In addition, in this embodiment, a material of the first stretchable electrode layer 120, the second stretchable electrode layers 140, and the third stretchable electrode layer 160 is, for example, poly(3,4-ethylenedioxythiophene) (PEDOT). The second stretchable electrode layers 140 and the third stretchable electrode layer 160 may be formed by coating the liquid PEDOT twice and solidifying the PEDOT. In this way, a segmented display control may be realized on the conformal electrophoretic display device 100.

In addition, in this embodiment, the stretchable electrophoretic display medium layer 130 may include multiple capsules 132 distributed therein. The stretchable electrophoretic display medium layer 130 may further include multiple electrophoretic particles 134 disposed in the capsules 132. The electrophoretic particles 134 may include black electrophoretic particles and white electrophoretic particles, or include colored electrophoretic particles. When applying voltages between the first stretchable electrode layer 120 and the second stretchable electrode layer 140, a distribution state of the electrophoretic particles of different colors may be changes through an electrophoretic effect to achieve different display effects.

In this embodiment, the electrophoretic display device 100 further includes a decorative layer 195 disposed on the first stretchable material layer 110, and the first stretchable material layer 110 is disposed between the first stretchable electrode layer 120 and the decorative layer 195. The decorative layer 195 may have various colors, patterns, or designs to enhance aesthetics and texture of the electrophoretic display device 100.

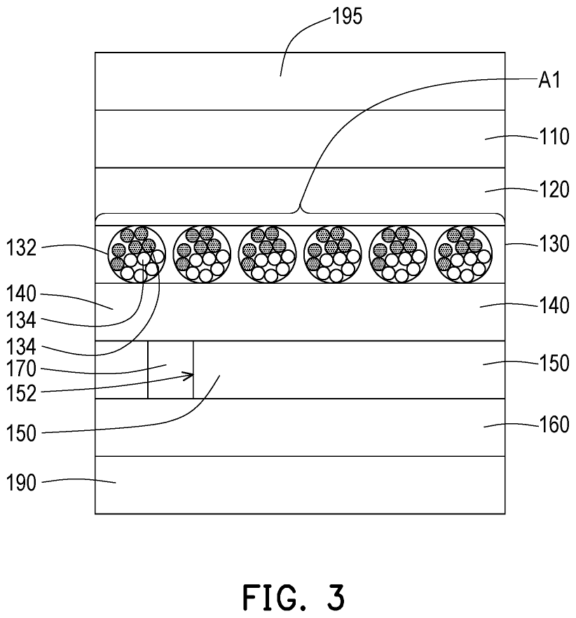

In another embodiment, referring to FIG. 3, the second stretchable electrode layer 140 may also be a single whole-layer structure disposed on the stretchable electrophoretic display medium layer 130, so that the stretchable electrophoretic display medium layer 130 forms the display region A1. In addition, the insulation layer 150 may have the through hole 152, and the through hole 152 is filled with the conductive material 170. The third stretchable electrode layer 160 is electrically connected to the second stretchable electrode layer 140 through the conductive material 170.

In summary, in the electrophoretic display device according to the embodiment of the disclosure, since the variety of stretchable materials are used to form the various layer structures, the electrophoretic display device according to the embodiment of the disclosure may be disposed on the curved surface and curve as the surface curves. In addition, the second stretchable electrode layers may also be separately disposed on the stretchable electrophoretic display medium layer, so that the stretchable electrophoretic display medium layer forms the display regions. Therefore, the electrophoretic display device of the embodiment of the disclosure may be disposed on the curved surface and curve as the surface curves, and may also be combined with segment technology.

What is claimed is:

1. An electrophoretic display device, comprising:
a first stretchable material layer;
a first stretchable electrode layer, disposed on the first stretchable material layer;
a stretchable electrophoretic display medium layer, disposed on the first stretchable electrode layer;
a plurality of second stretchable electrode layers, separately disposed on the stretchable electrophoretic display medium layer, allowing the stretchable electrophoretic display medium layer to form a plurality of display regions;
an insulation layer, disposed on the plurality of second stretchable electrode layers and having a plurality of through holes, wherein the plurality of through holes are respectively filled with a plurality of conductive materials; and
a third stretchable electrode layer, disposed on the insulation layer and electrically connected to the plurality of second stretchable electrode layers through the plurality of conductive materials, respectively.

2. The electrophoretic display device according to claim 1, further comprising a second stretchable material layer disposed on the third stretchable electrode layer.

3. The electrophoretic display device according to claim 2, wherein a material of the first stretchable material layer and the second stretchable material layer is amorphous polyethylene terephthalate.

4. The electrophoretic display device according to claim 1, further comprising a decorative layer disposed on the first stretchable material layer, wherein the first stretchable material layer is disposed between the first stretchable electrode layer and the decorative layer.

5. The electrophoretic display device according to claim 1, wherein a material of the first stretchable material layer is amorphous polyethylene terephthalate.

6. The electrophoretic display device according to claim 1, wherein a material of the first stretchable electrode layer, the plurality of second stretchable electrode layers, and the third stretchable electrode layer is poly(3,4-ethylenedioxythiophene).

7. An electrophoretic display device, comprising:
a first stretchable material layer;
a first stretchable electrode layer, disposed on the first stretchable material layer;
a stretchable electrophoretic display medium layer, disposed on the first stretchable electrode layer;
a second stretchable electrode layer, disposed on the stretchable electrophoretic display medium layer, allowing the stretchable electrophoretic display medium layer to form a display region;
an insulation layer, disposed on the second stretchable electrode layer and having a through hole, wherein the through hole is filled with a conductive material; and
a third stretchable electrode layer, disposed on the insulation layer and electrically connected to the second stretchable electrode layer through the conductive material.
